(19) United States
(12) Patent Application Publication
(10) Pub. No.: US 2007/0258300 A1
(43) Pub. Date: Nov. 8, 2007

(54) Functional verification of synchronized signals using random delays

(76) Inventors: Richard Kelderhouse, Wichita, KS (US); Thomas L. Langford II, Wichita, KS (US); Dennis E. Gates, Wichita, KS (US)

Correspondence Address: LSI CORPORATION, 1621 BARBER LANE, MS: D-106, MILPITAS, CA, 95035, US

(21) Appl. No.: 11/413,498

(22) Filed: Apr. 28, 2006

(51) Int. Cl. G11C 7/00

(52) U.S. Cl. 365/203

(57) ABSTRACT

A method and system for verifying synchronized signals if provided. The method may include receiving a signal from a first clock domain for synchronization. Further, a random number for the received signal may be generated and a reset signal imposed for utilization as a reference point for the received signal delay. In addition, the method may involve retrieving the random number for the received signal when a reset signal is removed. Moreover, the random number may be converted into a random delay value which may then be applied to the received signal.

### FIELD OF THE INVENTION

The present invention relates to the field of application specific integrated circuits (ASIC) and particularly to a method for verifying ASIC non-phase aligned clocks during register transfer level (RTL) verification utilizing a random delay methodology.

### BACKGROUND OF THE INVENTION

The functional design verification of Application Specific Integrated Circuits (ASICs) is a time consuming process. Finding functional problems early in the Register Transfer Level (RTL) verification process is essential to making the most efficient use of design resources and maintaining production schedule.

In today's complex designs, it is not uncommon for a design to include several non-phase aligned clocks in which multiple control and/or data signals must cross such clock domains to perform a given function. Further, to ensure that a signal is stable in the receiving clock domain, a two-stage synchronizer may be employed. Typically, such synchronizer includes a minimum of two flip-flops connected in series. The first flip-flop captures the signal provided that setup and hold conditions are met. However, if setup and hold conditions are not met, the first flip-flop may enter a meta-stable state. The second flip-flop is designed to prevent the meta-stable state from propagating into the logic. In such a situation, the signal is not captured in the first flip-flop until the second clock. Thus, the output of the second flip-flop may capture the required signal on the second or third clock edge of the receiving domain depending on the relative frequencies of the source and destination clock domains. Therefore, a window of when the signal is valid is created. Functionally, the design needs to be able to tolerate when the signal is valid and the various timing delays. During chip layout, due to the different sizes of the various clock domains, additional skew between clock domains may be added. Additional variation is inserted to account for variations in routing, process, temperature, voltage, and other similar factors.

The problem is how to perform design verification early in the design cycle that accounts for all of the aforementioned variations. Traditional RTL simulation lacks the ability to address the timing variation that is required to functionally test signals that cross clock domains. Typically, these delays are fixed and do not vary. If variation is introduced, most signals delay for the same amount of time. For example, all bits of an 8 bit data bus would have the same delay and thus tend to track each other. Further, such approach lacks the robustness to vary signals from each other that account for timing variations introduced by layout, process, temperature, and voltage.

In addition, gate level, prototype and production testing are also limited by their inability to detect a problem early. Such testing procedures do not easily allow for testing of timing variations between different clock domains. Further, the inability to identify design limitations early during the RTL verification stage may significantly impact the scheduling and cost of a product. First, delaying design verification until gate level simulation, may add schedule risk to a design. For example, if a problem is not identified until gate level simulation, such design fix must be either manually incorporated into the netlist or the layout must be restarted. Both options may result in schedule delay. Second, if the problem is not identified until prototype verification of the ASIC is performed, the schedule and cost impact becomes even greater for the design is timing closed and is now in silicon. Finally, if the problem escapes identification until chip production, the cost may be devastating to the product and the company.

Therefore, it would be desirable to provide a method for verifying ASIC non-phase aligned clocks during (RTL) verification which addresses the aforementioned limitations.

### SUMMARY OF THE INVENTION

Accordingly, the present invention is directed to a method and system for verifying synchronized signals. In a first aspect, the method may include receiving a signal from a first clock domain for synchronization. Further, a random number for the received signal may be generated and a reset signal imposed for utilization as a reference point for the received signal delay. In addition, the method may involve retrieving the random number for the received signal when a reset signal is removed. Moreover, the random number may be converted into a random delay value which may then be applied to the received signal. For clarity it should be pointed out that the term ‘received signal’ refers to the D input to the first storage element of a synchronizer.

In a further aspect of the present invention, an additional method for verifying synchronized signals is provided. The method may include receiving a signal from a first clock domain for synchronization generating a random number for the received signal. For example, the random delay is at least partially based on the time of a central processing unit (CPU). Further, the method may involve actuating a reset signal for utilization as a reference point for the received signal delay and retrieving the random number for the received signal when a reset signal is removed. In addition, the method may entail converting the random number into a random delay value. The random delay value may be copied to a user log file each time the random number is converted. Moreover, the random delay value may be applied to the received signal whereby the random delay value is utilized until an additional reset signal is imposed.

It is to be understood that both the foregoing general description and the following detailed description are exemplary and explanatory only and are not restrictive of the invention as claimed. The accompanying drawings, which are incorporated in and constitute a part of the specification, illustrate an embodiment of the invention and together with the general description, serve to explain the principles of the invention.

### BRIEF DESCRIPTION OF THE DRAWINGS

The numerous advantages of the present invention may be better understood by those skilled in the art by reference to the accompanying figures in which:

FIG. 1 is a flow diagram of a method for verifying synchronized signals in accordance with an exemplary embodiment of the present invention;

FIG. 2 is a port description for a model in accordance with an exemplary embodiment of the present invention;

FIGS. 3A through 3D provides exemplary code allowing the model illustrated in FIG. 2 to implement a random delay. The term random number refers to rand_num. The term random delay value refers to lbdly;

FIG. 4 provides exemplary code allowing the model illustrated in FIG. 2 to either apply a fixed delay determined by the user or no delay;

FIG. 5 provides exemplary code for gate level instantiation of a 2-stage synchronizer; and

FIG. 6 is a flow diagram of an additional method for verifying synchronized signals in accordance with an exemplary embodiment of the present invention.

### DETAILED DESCRIPTION OF THE INVENTION

Reference will now be made in detail to the presently preferred embodiments of the invention, examples of which are illustrated in the accompanying drawings. The method and system of the present invention permits validation of clock timing variation in application specific integrated circuits (ASIC). Particularly, the present invention may be utilized for identifying synchronization issues for non-aligned clocks (non-phase aligned) during chip design/production. Preferably, the method is implemented during register transfer level (RTL) verification. RTL verification occurs early in the design cycle prior to other simulations or modeling, such as gate simulation and prototype verification. By conducting the present method, users may identify clock issues associated with non-aligned clock signaling earlier in the chip design process thereby minimizing or eliminating expensive delays. In the foregoing manner, the method may assist in identifying stability issues associated with signals crossing various clock domain which may cause instability for the chip and the system.

The method of the present invention permits variation in clock signaling to identify issues with variable delays associated with included structures to prevent catastrophic chip and system failure due to synchronization issues and timing delays which typically are found late in chip design (e.g., delays associated with physical implementation of the circuitry in the wafer). Additionally, the method may permit improved chip design to account for time delay sources prior to fabricating test samples. Time delays typically are generated by skew between clock domains, variation in routing, process considerations, temperature, voltage, clock jitter, and other like factors which introduce or exacerbate signal delay and other clock signaling issues. The problem of signaling across different clock domains includes the need to ensure signals are of sufficient duration to be captured to guarantee the signal is kept valid for multiple clock cycles.

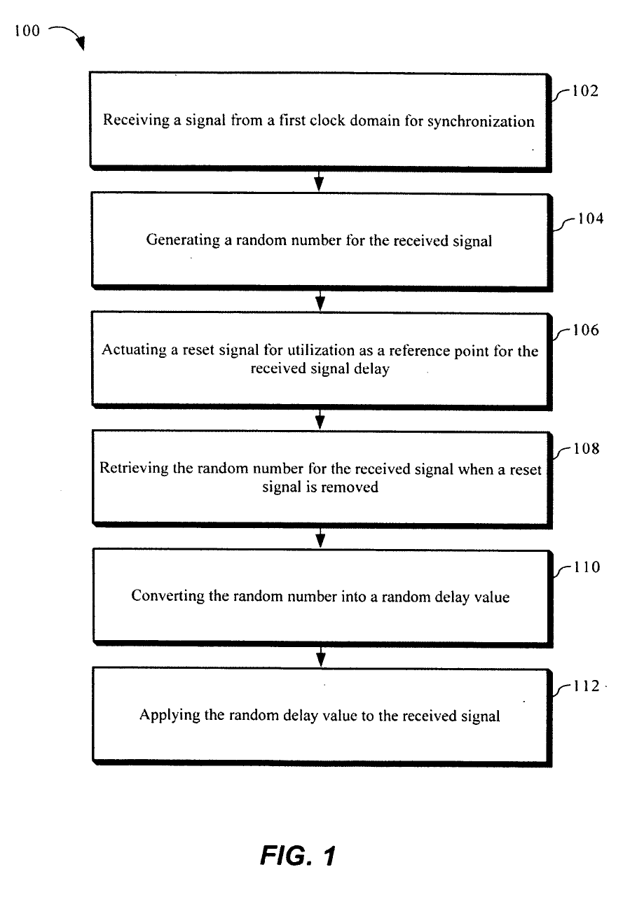

Referring to FIG. 1, a method 100 for verifying signal synchronization is discussed. The method 100 of the present invention permits introduction of a random delay in order to verify non-phase aligned clock signaling. For example, the effect of physical implementation of the design, with respect to clock synchronization issues, is detected earlier in the design process. As will be discussed below, the random delay, in some instances, may be at least partially based on a value which is not strictly “non-arbitrary”. For instance, while an arbitrary factor is applied, the seed used as a basis to select a random number is based on a central processing unit's (CPU) clock time. For example, a system implementing the present method 100 is utilized to simulate delays to ensure effective simulation of chip design to prevent design schedule delays in subsequent gate level or prototype verification due to delays associated with a signal crossing from a first clock domain to a second clock domain such as for non-phase aligned clock domains. In a preferred embodiment, the method may be implemented utilizing Institute of Electrical and Electronics Engineers (IEEE) Standard 1364 (Verilog language). The foregoing is an automated integrated design system for modeling/verifying ASIC designs. Verilog language may be preferable as such standard includes a random number generation functionality. Those of ordinary skill in the art will appreciate that the method of the present invention may be implemented utilizing various language and programming methodology as desired without departing from the scope and spirit of the present invention.

In an exemplary embodiment, the method 100 for verifying synchronized signals includes receiving a signal from a first clock domain for synchronization 102 and generating a random number for the received signal 104. For instance, the random number may be at least partially based on CPU clock time as a seed value. In the previous manner, the random number is included in the generating of the random delay value. Thus, various delays may be generated to verify functionality of the chip design. For example, delay variation may account for differing physical affects caused by routing, process, temperature, voltage, and the like. In another example, the method 100 may verify operability of a system for an increased signaling delay due to a physical factor. Therefore, the chip design is confirmed as being capable of tolerating the physical variation prior to a prototype verification step, which requires a prototype ASCI. Thus, signals crossing clock non-phase aligned domains may be tested earlier in the design process. Further, the presently disclosed verification may ensure that a signal may be held in a flip-flop for a sufficient number of cycles without encountering synchronization issues typically instigated as a result of a delay which is not identified by previous RTL verification which is tuned to a particular verification pattern set.

In further embodiments, generating the random number 104 may be part of the hardware description language utilized to design and verify the design. For example, a general purpose computer with Verilog software, having a random number generation capability, is implemented for ASIC model verification. A random factor may be applied to a value such as the CPU time. Thus, a unique delay value may be generated for each verification instance due to the imposition of the CPU time as a seed for generating the random number. In this manner, the ASIC design is verified for a random variety of delays to verify the stability of the non-phase aligned clock domains and signals crossing from a first clock domain to a second clock domain.

In an additional embodiment, the method 100 may include actuating a reset signal on the system for utilization as a reference 106. The reset signal may be utilized as a reference point for determination and/or verification of the applied delay. Upon removal of the reset signal the random number is called for utilization 108. Retrieving for the random number may additionally include obtaining the CPU clock time. For example, once the reset signal is removed, the random number and the CPU time is obtained as a seed value. The CPU time and the random number are implemented for converting the random number into a delay increment, which implements the CPU time as a “seed value” or component in determining the random delay value. The random delay value resulting in a unique delay value. For instance, the random delay value is changed for each synchronized signal. The method 100 may further include applying the random delay value to the received signal 110 thereby resulting in a delay in the signal. The delay value is implemented until a reset signal is applied or the simulation is restarted. In this manner, the signal is randomly delayed between clock domains so as to verify synchronization.

In another embodiment, the method 100 may include the additional step of permitting a user to define a fixed delay value. For example, the user may select to impose no delay on the signal or impose a user selected delay such as some delay, i.e., a user defined delay which is greater than no delay.

In a specific embodiment, the method 100 is implemented utilizing Institute of Electrical and Electronics Engineers (IEEE) Standard 1364 (Verilog language) a hardware description language. In the present embodiment, the following model may be used during simulation to generate the random numbers. The model may be used to represent the functionality of a single 2-stage synchronizer cell. Such cell is then instantiated as often as needed in the design for signals that cross clock domains.

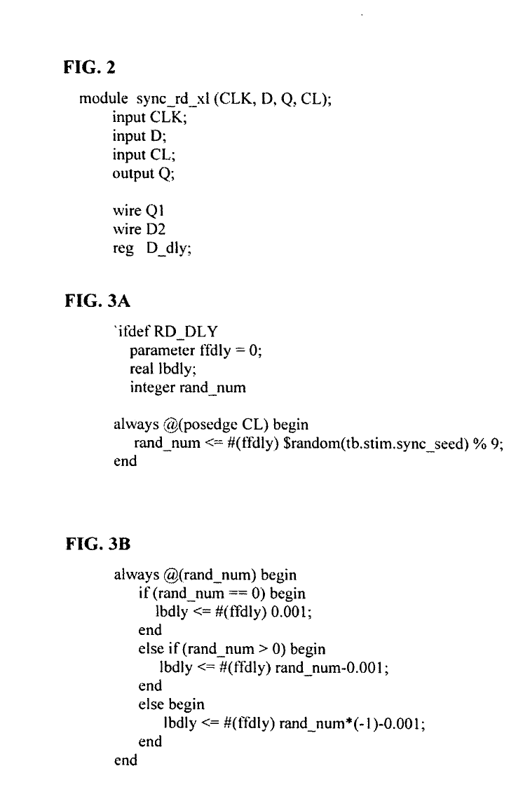

A port description for an exemplary model is provided in FIG. 2. The term CLK refers to the clock for the synchronizer cell. Further, D represents the signal being synchronized while CL denotes the reset signal used to initialize the registers used to perform the synchronizing function. In addition, Q denotes the output of the second stage of the synchronizer cell and may connect to other logic or ports in the ASIC design. Moreover, Q1 refers to an output signal wire delay and D2 to an input signal wire delay which represent the delay between stage 1 of the synchronizer and stage 2 of the synchronizer. D_dly register delay is the D input delay to stage 1 of the synchronizer.

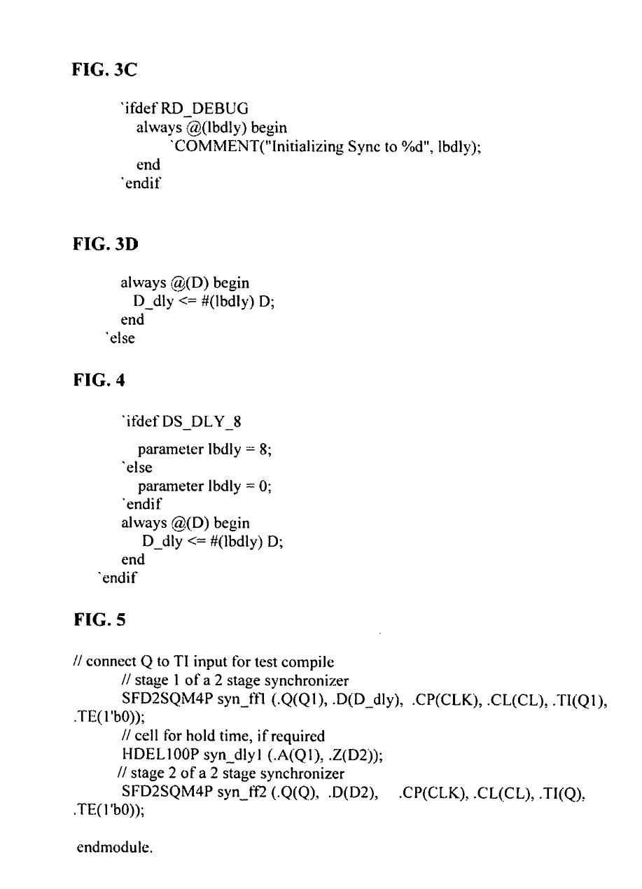

Referring to FIG. 3A, exemplary code allowing the model illustrated in FIG. 2 to implement a random delay is provided. For example, the random number portion of the model is begun by the following set of commands:

‘ifdef RD_DLY

parameter ffdly = 0;
real lbdly;
integer rand_num.

Further, retrieving the random number for the received signal when a reset signal is removed is performed by commands:

always @(posedge CL) begin

rand_num <= #(ffdly) $random(tb.stim.sync_seed) % 9;

end.

The reset signal may be used as a convenient reference point. The seed value for the random number generator function is based on the CPU time that each instance makes this call. Since the CPU basically performs a single function at a time, each instantiation gets a different random number thereby allowing each instance to ultimately be assigned a unique delay value. Such value may be used until reset is applied or the simulation is restarted. In an embodiment, the time value is not the simulation time stamp, but the CPU time. The random delay value may be logged and reused to allow the simulation to be re-run using the same delays

Referring to FIG. 3B, code for converting the random number into a random delay value is provided. As illustrated in FIG. 3B, exemplary code for converting the random value into a delay increment may include the following:

always @(rand_num) begin

if (rand_num == 0) begin

lbdly <= #(ffdly) 0.001;

end
else if (rand_num > 0) begin

lbdly <= #(ffdly) rand_num-0.001;

end
else begin

lbdly <= #(ffdly) rand_num*(−1)-0.001;

end

end.

In the preceding example, the delay value is 0.001, if the random number is equal to zero. Otherwise the random delay value is generated by decrementing, in this example by 0.001 after the random number is assured to be a positive value.

Referring to FIG. 3C, code for communicating the random delay value to the user in a log file for each instance is provided. For example, the random delay value may be copied to a user log file each time the random number is converted by the following code:

‘ifdef RD_DEBUG

always @(lbdly) begin

‘COMMENT(″Initializing Sync to %d″, lbdly);

end

‘endif.

Referring to FIG. 3D, exemplary code for applying the delay when the D input changes is provided. As illustrated by FIG. 3D, the delay may be applied by utilizing the following code:

always @(D) begin

D_dly <= #(lbdly) D;

end

‘else.

In the present embodiment, the delay effects when the signal is actually applied to the data input of the first stage of the synchronizer.

Referring to FIG. 4, exemplary code allowing a user to apply a fixed delay or no delay is provided. As illustrated in FIG. 4, a user defined fixed delay value or no delay may be applied by the following code:

‘ifdef DS_DLY_8

parameter lbdly = 8;

‘else

parameter lbdly = 0;

‘endif
always @(D) begin

D_dly <= #(lbdly) D;

end

′endif.

Referring to FIG. 5, exemplary code for a gate level instantiation of a 2-stage synchronizer is provided. As illustrated in FIG. 5, the gate level instantiation of the present method may be conducted as follows:

```
  // connect Q to TI input for test compile
  // stage 1 of a 2 stage synchronizer
  SFD2SQM4P syn_ff1 (.Q(Q1), .D(D_dly), .CP(CLK), .CL(CL),
  .TI(Q1),
```

.TE(1′b0));

```
  // cell for hold time, if required
  HDEL100P syn_dly1 (.A(Q1), .Z(D2));
// stage 2 of a 2 stage synchronizer
  SFD2SQM4P syn_ff2 (.Q(Q), .D(D2), .CP(CLK), .CL(CL),
  .TI(Q),
```

.TE(1′b0));
endmodule.

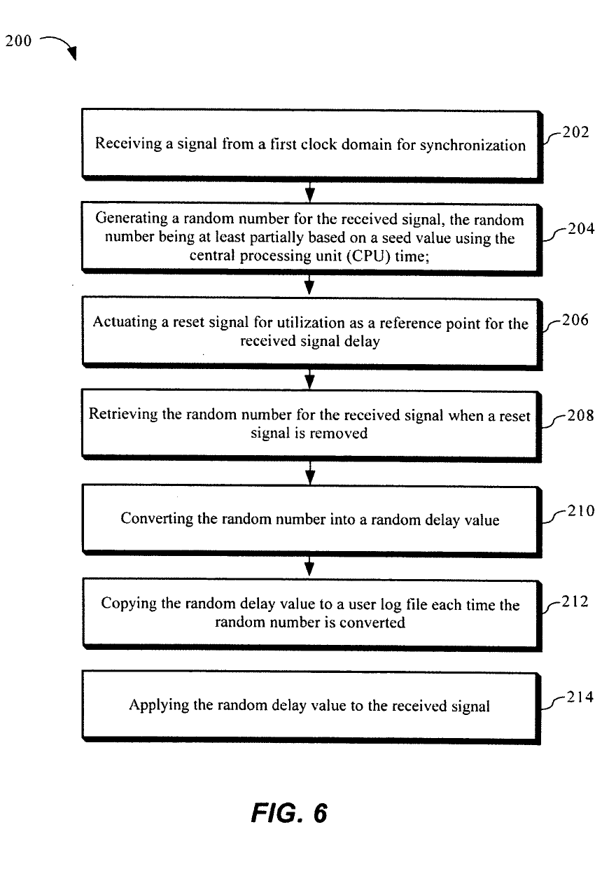

Referring to FIG. 6, an additional method 200 for verifying synchronized signals in accordance with an exemplary embodiment of the present invention is provided. The method 200 may include receiving a signal from a first clock domain for synchronization 202 and generating a random number for the received signal 204. For example, the random number is at least partially based on the time of a central processing unit (CPU). Further, the method 200 may involve actuating a reset signal for utilization as a reference point for the received signal delay 206 and retrieving the random number for the received signal when a reset signal is removed 208. In addition, the method 200 may entail converting the random number into a random delay value 210. The random delay value may be copied to a user log file each time the random number is converted 212. Moreover, the random delay value may be applied to the received signal 214 whereby the random delay value is utilized until an additional reset signal is imposed.

Although the invention has been described with a certain degree of particularity, it should be recognized that elements thereof may be altered by persons skilled in the art without departing from the spirit and scope of the invention. One of the embodiments of the invention can be implemented as sets of instructions resident in the memory of one or more information handling systems, which may include memory for storing a program of instructions and a processor for performing the program of instruction, wherein the program of instructions configures the processor and information handling system. Until required by the information handling system, the set of instructions may be stored in another readable memory device, for example in a hard disk drive or in a removable medium such as an optical disc.

It is understood that the specific order or hierarchy of steps in the processes disclosed is an example of exemplary approaches. Based upon design preferences, it is understood that the specific order or hierarchy of steps in the processes may be rearranged while remaining within the scope of the present invention. The accompanying method claims present elements of the various steps in a sample order, and are not meant to be limited to the specific order or hierarchy presented.

It is believed the system of the present invention and many of its attendant advantages will be understood by the foregoing description. It is also believed that it will be apparent that various changes may be made in the form, construction and arrangement of the components thereof without departing from the scope and spirit of the invention or without sacrificing all of its material advantages. The form herein before described being merely an explanatory embodiment thereof. It is the intention of the following claims to encompass and include such changes.

What is claimed is:

1. A method for verifying synchronized signals, comprising:
receiving a signal from a first clock domain for synchronization;
generating a random number for the received signal;
actuating a reset signal for utilization as a reference point for the received signal delay;
retrieving the random number for the received signal when a reset signal is removed; converting the random number into a random delay value; and
applying the random delay value to the received signal.

2. The method for verifying synchronized signals of claim 1, wherein the method is implemented utilizing Institute of Electrical and Electronics Engineers (IEEE) Standard 1364 (Verilog language).

3. The method for verifying synchronized signals of claim 1, wherein method is conducted during register transfer level (RTL) verification.

4. The method for verifying synchronized signals of claim 1, wherein the method is applied to the verification of an application specific integrated circuit (ASIC).

5. The method for verifying synchronized signals of claim 1, wherein the random number is a unique random number based on using the central processor unit (CPU) time as a seed value and used to generate a unique random delay value for each synchronizer.

6. The method for verifying synchronized signals of claim 1, wherein the random number is implemented until an additional reset signal is imposed or the method is restarted.

7. The method for verifying synchronized signals of claim 1, wherein the random delay value is copied to a user log file for each time the random number is converted.

8. The method for verifying synchronized signals of claim 1, wherein applying the random delay value is unique for each synchronizer

9. The method for verifying synchronized signals of claim 1, further comprising permitting a user to define a fixed delay value.

10. The method for verifying synchronized signals of claim 9, wherein the fixed delay value is approximately zero.

11. A method for verifying synchronized signals, comprising:
receiving a signal from a first clock domain for synchronization;
generating a random number for the received signal, the random number being at least partially based on a central processing unit (CPU) time as a seed value;
actuating a reset signal for utilization as a reference point for the received signal delay;
retrieving the random number for the received signal when a reset signal is removed;
converting the random number into a random delay value;
copying the random delay value to a user log file each time the random number is converted; and
applying the random delay value to the received signal, wherein the random delay value is utilized until an additional reset signal is imposed.

12. The method for verifying synchronized signals of claim 11, wherein the method is implemented utilizing Institute of Electrical and Electronics Engineers (IEEE) Standard 1364 (Verilog language).

13. The method for verifying synchronized signals of claim 11, wherein the method is conducted during register transfer level (RTL) design verification.

14. The method for verifying synchronized signals of claim 11, wherein the method is applied to the verification of an application specific integrated circuit (ASIC).

15. The method for verifying synchronized signals of claim 11, wherein applying the random delay value is unique for each synchronizer.

16. The method for verifying synchronized signals of claim 11, further comprising permitting a user to define a fixed delay value.

17. The method for verifying synchronized signals of claim 16, wherein the fixed delay value is approximately zero.

18. A system for verifying synchronized signals during register transfer level verification, comprising:
means for generating a random delay to a received clock system;
means for retrieving the generated random delay upon removal of a reset signal; and
means for converting the generated random delay into a random delay value.

19. The system for verifying synchronized signals of claim 18, wherein the system implements Institute of Electrical and Electronics Engineers (IEEE) Standard 1364 (Verilog language).

20. The system for verifying synchronized signals of claim 18, wherein the random number is at least partially based on using the central processor unit (CPU) time as a seed value and converting the random number to a random delay value.
